(19) United States
(12) Patent Application Publication
(10) Pub. No.: US 2004/0085082 A1
(43) Pub. Date: May 6, 2004

(54) High -frequency scan testability with low-speed testers

(76) Inventor: Kent Richard Townley, San Jose, CA (US)

Correspondence Address: FISH & RICHARDSON P.C., 1425 K STREET, N.W., 11TH FLOOR, WASHINGTON, DC, 20005-3500, US

(21) Appl. No.: 10/283,326

(22) Filed: Oct. 30, 2002

(51) Int. Cl. G01R 31/26

(52) U.S. Cl. 324/765

(57) ABSTRACT

A clock generation circuit for providing high-frequency scan testability with a low-speed tester includes a clock selector and control logic. The clock selector receives a reference clock signal and a high-frequency clock signal and produces an output signal selected from the reference clock signal and the high-frequency clock signal based on a clock selector control signal. The control logic that receives a capture signal and produces the clock selector control signal to modify the clock selector output signal in response to the capture signal. The clock selector output signal may be used to provide high-frequency scan testability with a low-speed tester.

### TECHNICAL FIELD

This description is directed to providing high-frequency scan testability using low-speed testers.

### BACKGROUND

As the density of very large scale integration (VLSI) circuits increases, the testability of those circuits decreases. Application-specific integrated circuits (ASIC) often include millions of gates in a system-on-chip (SoC) configuration with embedded processor cores (often supplied by a third party), memory, and application-specific logic. Testing such circuits is a daunting task, as shown by the quantity of research in design-for-test (DFT) techniques and built-in self-test (BIST) functionality.

One common technique for testing a simple circuit, such as an AND gate, is to apply a series of input vectors and observe the output of the circuit to verify the appropriate behavior. For example, an AND gate includes two inputs, A and B, and an output C. The output C should be the logical AND of the inputs A and B. A series of test vectors, [(A₁,B₁),C₁], [(A₂,B₂),C₂], . . . [(Aₙ,Bₙ),Cₙ], may be used to verify the operation of the AND gate. For example, the first vector may be [(0,0),0], i.e., a “0” is applied to each of A and B, and the expected output is “0”. Similarly, for the test vector [(1,1),1], a “1” is applied to each of A and B and the expected output of the AND gate is “1.” If the expected output is not observed, then the circuit is defective. As circuit complexity increases, the same basic technique can be applied by making components of the circuit observable and controllable so that the inputs to a circuit or a component of a complex integrated circuit may be controlled and the corresponding output observed.

One technique used to make integrated circuits both controllable and observable is to incorporate scan registers into the circuit design. For example, Huffman illustrated that sequential logic circuits may be modeled as combinatorial logic in conjunction with a register (e.g., latch, flip-flop) to store state. D. A. Huffman, “The Synthesis of Sequential Switching Circuits,” J. Franklin Insitute, vol. 257, no.3, pp.161-190 (March 1954). The register includes an input from the combinatorial logic so that the state may be changed, an output to the combinatorial logic so that the state may be used by the logic, and a clock signal. The register may be modified to be a scan register to implement scan-based DFT. The scan register additionally includes a mode signal to switch the scan register between a normal mode and a test mode; an input signal to receive a test vector to be used by the combinational logic circuit; and an output signal so that test results may be observed.

To reduce the number of pins needed in an integrated circuit employing scan-based DFT, a series of scan registers may be connected in a chain such that scan inputs and outputs may be serially shifted through the chain to reduce the number of pins needed to fully test the integrated circuit.

### SUMMARY

In one general aspect, a clock generation circuit for providing high-frequency scan testability with a low-speed tester includes a clock selector and control logic. The clock selector receives a reference clock signal and a high-frequency clock signal and produces an output signal selected from the reference clock signal and the high-frequency clock signal based on a clock selector control signal. The control logic receives a capture signal and produces the clock selector control signal to modify the clock selector output signal in response to the capture signal. The clock selector output signal may be used to provide high-frequency scan testability with a low-speed tester. The reference clock signal may be received from tester hardware.

In some implementations, the clock generation circuit also includes a frequency multiplier that receives the reference clock signal and produces the high-frequency clock signal. The frequency multiplier may include a phase-locked loop that uses the reference clock signal and a feedback clock signal to produce the high-frequency clock signal, as well as a divider circuit that uses the high-frequency clock signal to produce the feedback clock signal. The divider circuit may be configurable to adjust the frequency of the high-frequency clock signal. The high-frequency clock signal may be provided, for example, as a multiple of the reference clock signal. Implementations may use a multiplexer for the clock selector.

The clock generation circuit also may include a clock gater circuit. The clock gater circuit uses a clock mask control signal generated by the control logic and the high-frequency clock signal to produce a gated clock signal that is received by the clock selector. In this implementation, the clock selector produces an output signal selected from the reference clock signal, the high-frequency clock signal, and the gated clock signal based on the clock selector control signal. The clock gater circuit may include a transparent latch. The clock gater circuit passes the high-frequency clock signal as the gated clock signal when the clock mask control signal is asserted and latches the gated clock signal when the clock mask control signal is deasserted.

The clock generation circuit uses the clock selector to produce an output signal that has approximately the same average frequency as the reference clock signal. The output signal includes portions having the same frequency as the high-frequency clock signal and portions having the same frequency as the reference clock signal.

In another general aspect, providing high-frequency scan testability with low-speed testers includes receiving a first clock signal, receiving a second clock signal having a higher frequency than the first clock signal, and producing an output clock signal by selectively outputting the first clock signal or the second clock signal in response to a control signal. The output clock signal is operable to test a circuit under test at frequency of the second clock signal using a tester device operating at the frequency of the first clock signal.

The details of one or more implementations are set forth in the accompanying drawings and the description below. Other features will be apparent from the description and drawings, and from the claims.

### DESCRIPTION OF DRAWINGS

FIG. 1 is a block diagram of a system using a clock generator to test high-performance circuits using lower-frequency tester hardware.

FIG. 2 is a timing diagram for the system shown in FIG. 1.

FIG. 3 is a block diagram of a detailed implementation of a clock generator that may be used in the system shown in FIG l.

FIG. 4 is a timing diagram for the system shown in FIG. 3.

FIG. 5 is a timing diagram for the system shown in FIG. 3 using a multiple cycle clock cycle.

### DETAILED DESCRIPTION

The performance of microprocessors has improved more quickly than the performance of tester hardware used to detect manufacturing defects and speed grade production parts. The gap in frequencies between tester hardware and high-performance microprocessors has widened to the point where tester hardware is either too costly or not fast enough to adequately test circuits using conventional techniques.

Many manufacturers desire a simple scan-based test approach for both detecting manufacturing defects and speed grading production parts. The most common type of scan architecture is muxed-based scan in which a series of scan registers may be used to load input test vectors into circuit components and view the resulting output from that test vector. In a typically scan architecture, the scan clock and the capture clock are the same. Using tester hardware in a scan architecture typically requires the tester hardware to operate at the same speed as the circuit under test to adequately detect manufacturing defects and speed grade production parts.

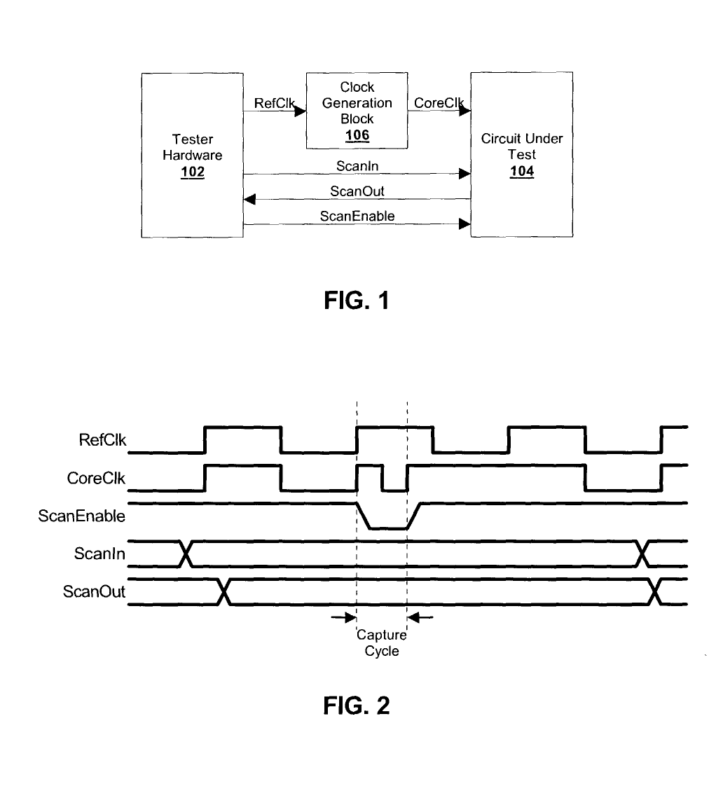

High-performance circuits may be tested using low-speed testing equipment. In particular, referring to FIG. 1, tester hardware 102 may be used to test a high-performance circuit under test (“CUT”) 104 using a clock generation block 106 to generate a core clock signal (CoreClk) using a reference clock signal (RefClk). The RefClk signal may be generated by any means. For example, the RefClk signal may be provided by the tester hardware 102, by a clock generation device, or by the clock generation block 106. The RefClk is used by the clock generation block 106 to generate the CoreClk signal used to clock scan registers in the CUT 104.

The CoreClk signal is controlled to permit the tester hardware 102 to scan in test vectors and scan out captured data at a frequency supported by the tester hardware. If the operating frequency of the tester hardware 102 is less than the operating clock frequency of the CUT 104, the hardware tester 102 may not be able to properly detect manufacturing defects in the CUT 104 and ensure proper operation at the desired operating speed. However, the frequency of the CoreClk signal may not be increased beyond the performance constraints of the tester hardware 102. The clock generation block 106 may modify the CoreClk signal to better support at-speed testing of high-performance circuits using lower-speed testing hardware by momentarily increasing the frequency of the CoreClk signal during capture cycles. This technique allows a circuit component of the CUT 104 to be operated at-speed while a test vector is being processed, while the test hardware 102 scans in test vectors and scans out captured data at lower frequencies.

The clock generation block 106 may be disposed within the tester hardware 102 (e.g., as part of an electronic design automation (EDA) tool) or within the CUT 104, or may be embodied as a separate circuitry providing an interface between the tester hardware 102 and the CUT 104.

FIG. 2 provides a timing diagram that illustrates the operation of the system of FIG. 1. The RefClk signal provides a reference clock at a frequency compatible with the tester hardware 102. This signal allows normal operation of the tester hardware 102 in scanning test vectors into and captured data out of the CUT 104. The RefClk signal is used to generate the CoreClk signal for use in clocking the serial scan chain. When a component of the CUT 104 is being tested, the ScanEnable signal is asserted. The clock generation block 106 then increases the frequency of the CoreClk signal until the ScanEnable signal is deasserted, which indicates the completion of a capture cycle.

In this system, the tester hardware 102 is clocked by the RefClk signal and the CUT 104 is clocked by the CoreClk signal. Since the scan registers in the CUT 104 are capable of operating at the operating speed of the CUT 104, momentarily increasing the frequency of the CoreClk signal permits quicker propagation of data through the scan chain. To prevent the tester hardware 102 from getting out of sync with the CUT 104, the CoreClk signal is delayed as shown in FIG. 2 such that the average frequencies of the RefClk signal and the CoreClk signal are substantially similar.

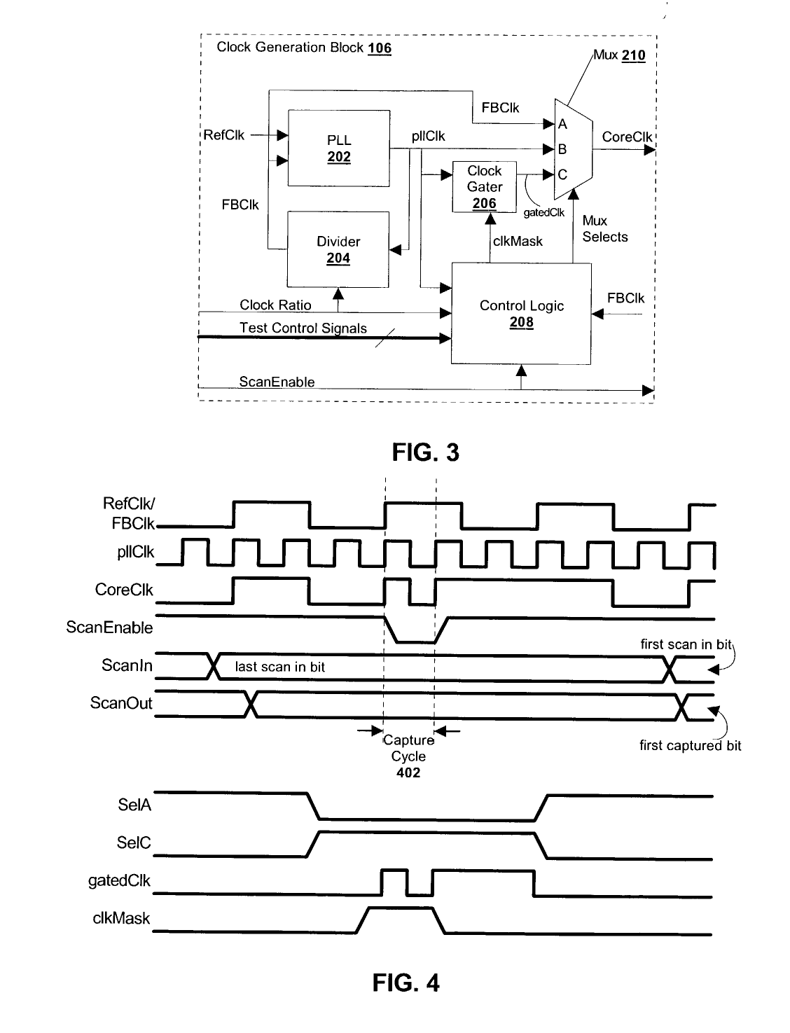

FIG. 3 shows a detailed implementation of a clock generation block 106 that may be used in the system of FIG. 1. The clock generation block 106 includes a PLL circuit 202, a divider circuit 204, a clock gater 206, control logic 208, and a multiplexer (“mux”) 210. The phase-locked loop (PLL) circuit 202 is used in combination with the divider circuit 204 to increase the frequency of the reference clock signal (RefClk) by a determined multiple. For example, the PLL circuit 202 may be used to increase the frequency of the RefClk signal by any factor (e.g., 1.5, 2, 3.25, etc.). In a typical phase-locked loop multiplier circuit, the divider circuit 204 is a divide-by-n counter that generates a feedback clock signal (FBClk). The PLL circuit 202 uses the FBClk and the RefClk signals to generate an output clock signal (pllClk) with a frequency that is n times the frequency of the RefClk signal. In this implementation, the frequency multiplier factor n may be specified using a clock ratio signal.

In this implementation, the system uses the reference clock of the tester hardware 102 to generate a higher-frequency signal for testing at-speed or at a higher speed than the tester hardware 102 normally allows. This high-frequency signal, pllClk, is merged with the slower RefClk signal to allow data capture to occur at-speed while the propagation of data through the scan chain occurs at speeds supported by the tester hardware 102.

In some implementations, the clock generation block 106 may be used to decrease the frequency of the capture cycle. For example, the PLL circuit 202 may be used to decrease the frequency of the RefClk signal by using a factor less than 1 (e.g., 0.25, 0.5, etc.). A factor of 0.25 would result in a capture cycle frequency that is a factor of 4 slower than the RefClk signal. This allows the tester hardware 102 to test the operation of the CUT 104 at lower frequencies.

As mentioned above, after executing the capture cycle at-speed, the CoreClk signal may be delayed such that the tester hardware 102 and the CUT 104 do not get out of sync. The combination of the PLL circuit 202 and the divider circuit 204 may be used to synthesize a multiple frequency clock for at-speed scan testing. This signal may be gated using clock gater 206 to synthesize a signal including a portion of the higher-frequency pllClk signal and a delay. The clock gater 206 includes an input control signal clkMask. In some implementations, the clock gater 206 is a transparent latch. When the clkMask signal is asserted, the input pllClk signal is passed to the output gatedclk signal. When the clkMask signal is deasserted, the value is latched. The clock gater 206 may be used to synthesize a signal including, for example, one or more clock signals followed by any desired delay as is discussed below with reference to FIG. 4.

The clkMask signal is generated by a control logic circuit 208 that receives a clock ratio signal, one or more test control signals, pllClk, FBClk, and ScanEnable as inputs. Based on the input signals, the control logic circuit 208 generates the clkMask signal and selection signals to control mux 210. The mux 210 generates the CoreClk signal by selecting one of three possible inputs based on the mux selects determined by the control logic circuit 208. The mux 210 allows selection of the FBClk signal, the pllClk signal, or the gatedclk signal.

The control logic circuit 208 waits for the testing hardware 102 to assert the ScanEnable signal to capture data in the CUT 104. While waiting for the ScanEnable signal to be asserted, the control logic circuit 208 asserts control signals to select the FBClk. Thus, the CoreClk is the same frequency as that used by the testing hardware 102. When ScanEnable is asserted, the control logic 208 asserts the clkMask signal which causes the clock gater 206 to pass the high-frequency clock (pllClk) to input C of the mux 210. The control logic circuit 208 also asserts control signals to have the mux 210 select the gatedclk signal.

When the ScanEnable signal is deasserted, the control logic circuit 208 delays before resuming selection of the FBClk signal. By deasserting the clkMask signal, the gatedclk signal remains latched. When the appropriate delay has been inserted, the control logic 208 asserts mux control signals to select the FBClk signal until the next ScanEnable is asserted.

In some implementations, the frequency of pllClk is a fixed multiple of the RefClk signal. In these implementations, no clock ratio signal is needed. When a clock ratio signal is used to control the divider circuit 204, the signal may also be passed to the control logic circuit 208 to adjust the delay inserted after a high-speed capture cycle.

Some implementations may use additional test control signals as shown in FIG. 3 to provide additional functionality. These signals may be used, for example, to allow selection between high-speed capture cycles and low-speed capture cycles so that various components of the CUT 104 may be tested at different speeds.

FIG. 4 is an exemplary timing diagram for the clock generation block 106 of FIG. 3. The RefClk signal is the input reference signal for the PLL circuit 202. This signal is generated, for example, by the tester hardware 102 or by an external clock circuit. The RefClk signal is substantially similar to the feedback signal FBClk created by dividing the output of the PLL circuit 202 by the clock ratio.

The PLL circuit 202 generates a pllClk signal that is a multiple of the RefClk signal. This signal is used to synthesize the higher frequency used to perform at-speed testing. In this example, the clock ratio is three so that the pllClk signal has a frequency three times the frequency of the RefClk signal.

The clock generation block 106 merges the pllClk signal and the RefClk signal, and inserts any needed delays, to create the CoreClk signal that is used to clock the scan chain registers in the CUT 104. In this example, the CoreClk signal mimics the RefClk signal until a capture cycle is indicated by the ScanEnable signal. During the capture cycle, the CoreClk signal frequency is increased to that of the pllClk signal.

After one clock cycle, ScanEnable is deasserted and the CoreClk signal is held high until one clock cycle of RefClk is complete. Then CoreClk again mimics RefClk until the next capture cycle begins. In the timing diagram shown, CoreClk and RefClk each complete the same number of clock cycles, with the frequency of CoreClk increased to that of pllClk during the capture cycle.

A gatedClk signal is generated by the clock gater 206. The gatedclk signal is used to synthesize the high-frequency clock using the pllClk signal. The gatedclk signal can then be merged with the RefClk signal to synthesize the CoreClk signal.

The ScanIn and ScanOut signals illustrate an exemplary propagation of signals into and out of the scan chain in the CUT 104. Test vectors are asserted through ScanIn by the tester hardware 102 and captured data is received through the ScanOut. The tester hardware 102 asserts ScanIn signals and reads ScanOut signals at the frequency of the RefClk signal.

The remaining signals shown in FIG. 4 illustrate the control signals asserted by control logic circuit 208. The “SelA” and “SelC” signals indicate mux control signals to select the FBClk signal or the gatedClk signal, respectively. Because the mux 210 can select between three inputs, a two bit control signal is typically used. For example, a mux select control signal of “00” may be used to select the “A” input, “01” to select the “B” input, and “10” to select the “C” input. In this example, the pllClk input to the mux 210 is not used, so only one control bit is needed. For example, “0” may be used to select “A” and “1” may be used to select “C.” Finally, the clkMask signal is asserted by the control logic circuit 208 to pass the high-frequency pllClk through the clock gater 206.

In summary, low-speed tester hardware 102 may be used to test a high-frequency circuit under test 104 with conventional scan-chain testing by synthesizing a clock signal that momentarily increases the frequency of the clock signal used by the scan chain in the CUT 104. By inserting a delay to compensate for the momentary frequency increase, the tester hardware 102 may operate at the frequency of a low-speed reference clock while capture cycles occur at higher speed.

For example, the techniques described herein may be used to test a 2.0 GHz circuit using 500 MHz tester hardware. By setting the clock ratio to four, the clock generation block 106 generates a 500 MHz clock signal until the system enters a capture cycle. The clock generation block 106 then momentarily increases the frequency of the clock signal to 2.0 GHz for one clock cycle. The system then holds the signal for the equivalent of three 2.0 GHz clock signals to permit one 500 MHz clock cycle to complete. Then, the system resumes generation of a 500 MHz clock signal until the next capture cycle. This allows the 500 MHz tester hardware to issue data into the scan chain and receive captured data from the scan chain at 500 MHz while captures may actually occur at 2.0 GHz within the CUT 104. Thus, the 2.0 GHz circuit may be tested at speed using slower (and less expensive) tester hardware 102.

In addition, the tester hardware 102 may be used in this manner to test high-performance circuits using conventional scan-chain testing techniques with no modification to the tester hardware 102.

The implementations described above provide a technique to adjust the capture cycle frequency independently of the frequency of a reference clock signal. Increasing or decreasing capture cycle frequency increases testing effectiveness without necessitating significant modification to the testing hardware 102. The techniques described above allow testing by effectively driving the CUT 104 at speed for a single clock cycle. In some circuits, a single, at-speed capture cycle is insufficient to properly test the circuit. For example, some circuits use time-borrowing techniques to provide increased performance. Instead of waiting for a signal to be registered in a flip-flop, signals may be propagated through a transparent latch so that a portion of the circuit may borrow time from the previous clock cycle. To properly test some circuits, it would be desirable to provide multiple at-speed capture cycles.

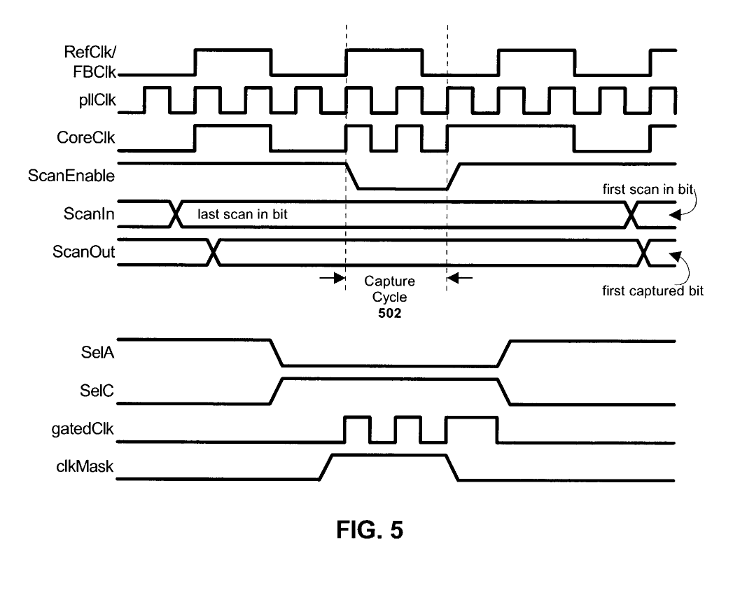

Referring to FIG. 5, the implementations described above also may be used to support multiple at-speed capture cycles. The number of cycles used in the capture period may be predetermined, determined by the control logic 208, or may be defined by the test control signals. FIG. 5 is a timing diagram showing a 2-cycle capture period using two consecutive cycles of the pllClk signal. To generate a two-cycle scan period, the control logic 208 asserts clkMask for two periods of the pllClk signal. This causes the clock gater 206 to generate the gatedclk signal having two clock periods of the pllClk signal which is selected by the mux 210 for propagation as the CoreClk signal.

In the implementation shown in FIG. 5, the scan chain in the CUT 104 is clocked twice in perhaps rapid succession. This may interfere with the operation of the hardware tester 102 receiving captured data from the scan chain because the hardware tester 102 is unable to operate at the higher clock frequency. Thus, data scanned out during the first clock period of the capture cycle may not be readable by the tester hardware 102. One solution to this problem is to insert delays when necessary to prevent data from being scanned out of the CUT 104 before the last cycle of a multi-cycle capture period.

In some implementations, the test control signals received by control logic 208 may indicate how many cycles to include in a multi-cycle capture period. For example, the test control signals may include two signals used to specify a number of cycles from 1 to 4. Alternatively, the test control signals may be configured to select from a predetermined set of possible capture cycle periods, such as between 1, 2, 4, or 8 cycles.

The examples described above use a PLL circuit 202 to generate a high-speed clock signal. However, any conventional clock generation techniques also may be used to create a high-frequency signal to merge with the reference clock signal as described.

In addition to high-frequency scan testability using low-speed tester schemes using hardware (e.g., within a microprocessor or microcontroller), implementations also may be embodied in software disposed, for example, in a computer usable (e.g., readable) medium configured to store the software (e.g., computer readable program code, data, etc.). The software enables the functions, fabrication, modeling, simulation, and/or testing of the systems and techniques disclosed herein. For example, this can be accomplished through the use of general programming languages (e.g., C, C++), GDSII, hardware description languages (HDL) including Verilog HDL, VHDL, AHDL (Altera HDL) and so on, or other available databases, programming and/or circuit (i.e., schematic) capture tools. The software can be disposed in any known computer usable medium including semiconductor, magnetic disk, optical disk (e.g., CD-ROM, DVD-ROM) and as a computer data signal embodied in a computer usable (e.g., readable) transmission medium (e.g., carrier wave or any other medium including digital, optical, or analog-based medium). As such, the software can be transmitted over communication networks including the Internet and intranets.

A number of implementations have been described. Nevertheless, it will be understood that various modifications may be made. Accordingly, other implementations are within the scope of the following claims.

What is claimed is:

1. A clock generation circuit for providing high-frequency scan testability with a low-speed tester, the clock generation circuit comprising:
a clock selector that receives a reference clock signal and a high-frequency clock signal, the clock selector producing an output signal selected from the reference clock signal and the high-frequency clock signal based on a clock selector control signal; and
control logic that receives a capture signal and produces the clock selector control signal to modify the clock selector output signal in response to the capture signal,
wherein the clock selector output signal may be used to provide high-frequency scan testability with a low-speed tester.

2. The clock generation circuit of claim 1 wherein the reference clock signal is received from tester hardware.

3. The clock generation circuit of claim 1 further comprising a frequency multiplier that receives the reference clock signal and produces the high-frequency clock signal.

4. The clock generation circuit of claim 3 wherein the frequency multiplier includes:
a phase-locked loop that receives the reference clock signal and a feedback clock signal and produces the high-frequency clock signal; and
a divider circuit that receives the high-frequency clock signal and produces the feedback clock signal.

5. The clock generation circuit of claim 4 wherein the divider circuit is configurable to adjust the frequency of the high-frequency clock signal.

6. The clock generation circuit of claim 4 wherein the frequency of the high-frequency clock signal is a multiple of the reference clock signal.

7. The clock generation circuit of claim 1 wherein the clock selector is a multiplexer.

8. The clock generation circuit of claim 1 further comprising:
a clock gater circuit, the clock gater circuit receiving a clock mask control signal generated by the control logic and the high-frequency clock signal, the clock gater circuit producing a gated clock signal that is received by the clock selector,
such that the clock selector produces an output signal selected from the reference clock signal, the high-frequency clock signal, and the gated clock signal based on the clock selector control signal.

9. The clock generation circuit of claim 1 wherein the clock gater circuit includes a transparent latch.

10. The clock generation circuit of claim 9 wherein the clock gater circuit passes the high-frequency clock signal as the gated clock signal when the clock mask control signal is asserted.

11. The clock generation circuit of claim 9 wherein the clock gater circuit latches the gated clock signal when the clock mask control signal is deasserted.

12. The clock generation circuit of claim 1 wherein the clock selector output signal has approximately the same average frequency as the reference clock signal.

13. The clock generation circuit of claim 12 wherein clock selector output signal includes portions that are the same frequency as the high-frequency clock signal and portions that are the same frequency as the reference clock signal.

14. A computer-readable medium comprising an integrated circuit embodied in software, the integrated circuit comprising:
a clock selector that receives a reference clock signal and a high-frequency clock signal, the clock selector producing an output signal selected from the reference clock signal and the high-frequency clock signal based on a clock selector control signal; and
control logic that receives a capture signal and produces the clock selector control signal to modify the clock selector output signal in response to the capture signal,
wherein the clock selector output signal may be used to provide high-frequency scan testability with a low-speed tester.

15. The computer-readable medium of claim 14 wherein the reference clock signal is received from tester hardware.

16. The computer-readable medium of claim 14 further comprising a frequency multiplier that receives the reference clock signal and produces the high-frequency clock signal.

17. The computer-readable medium of claim 16 wherein the frequency multiplier includes:
a phase-locked loop that receives the reference clock signal and a feedback clock signal and produces the high-frequency clock signal; and
a divider circuit that receives the high-frequency clock signal and produces the feedback clock signal.

18. The computer-readable medium of claim 17 wherein the divider circuit is configurable to adjust the frequency of the high-frequency clock signal.

19. The computer-readable medium of claim 17 wherein the frequency of the high-frequency clock signal is a multiple of the reference clock signal.

20. The computer-readable medium of claim 14 wherein the clock selector is a multiplexer.

21. The computer-readable medium of claim 14 further comprising:
a clock gater circuit, the clock gater circuit receiving a clock mask control signal generated by the control logic and the high-frequency clock signal, the clock gater circuit producing a gated clock signal that is received by the clock selector,
such that the clock selector produces an output signal selected from the reference clock signal, the high-frequency clock signal, and the gated clock signal based on the clock selector control signal.

22. The computer-readable medium of claim 14 wherein the clock gater circuit includes a transparent latch.

23. The computer-readable medium of claim 22 wherein the clock gater circuit passes the high-frequency clock signal as the gated clock signal when the clock mask control signal is asserted.

24. The computer-readable medium of claim 22 wherein the clock gater circuit latches the gated clock signal when the clock mask control signal is deasserted.

25. The computer-readable medium of claim 14 wherein the clock selector output signal has approximately the same average frequency as the reference clock signal.

26. The computer-readable medium of claim 25 wherein clock selector output signal includes portions that are the same frequency as the high-frequency clock signal and portions that are the same frequency as the reference clock signal.

27. A computer data signal embodied in a transmission medium comprising:
computer-readable program code for describing a clock generation circuit for providing high-frequency scan testability with a low-speed tester, the program code including:
a first program code segment for describing a clock selector that receives a reference clock signal and a high-frequency clock signal, the clock selector producing an output signal selected from the reference clock signal and the high-frequency clock signal based on a clock selector control signal; and
a second program code segment for describing control logic that receives a capture signal and produces the clock selector control signal to modify the clock selector output signal in response to the capture signal;
wherein the clock selector output signal may be used to provide high-frequency scan testability with a low-speed tester.

28. A method for providing high-frequency scan testability with low-speed testers, the method comprising:
receiving a first clock signal;
receiving a second clock signal, the second clock signal having a higher frequency than the first clock signal; and
producing an output clock signal by selectively outputting the first clock signal or the second clock signal based in response to a control signal;
wherein the output clock signal is operable to test a circuit under test at frequency of the second clock signal using a tester device operating at the frequency of the first clock signal.

29. The method of claim 28 wherein the frequency of the second clock signal is a multiple of the frequency of the first clock signal.

30. The method of claim 28 wherein the first clock signal is received from the tester device.

31. The method of claim 28 further comprising producing the second clock frequency from the first clock frequency using a frequency multiplier circuit.

32. The method of claim 31 wherein the frequency multiplier circuit includes a phase-locked loop.

33. The method of claim 28 wherein the control signal is a scan enable signal generated by the tester device.

34. The method of claim 28 wherein the output clock signal has approximately the same average frequency as the first clock signal.

35. The method of claim 34 wherein the output clock signal includes portions that are the same frequency as the first clock signal and portions that are the same frequency as the second clock signal.

36. A system for testing a device comprising:
a circuit-under-test including:
a clock input signal;
a capture input signal;
a test vector input signal; and
a test vector output signal;
a clock generation block that generates the clock input signal; and
tester hardware device operable to test the circuit-under-test by asserting test vectors using the test vector input signal, capturing test results using the capture input signal, and receiving the test results from the test vector output signal;
wherein the clock input signal generated by the clock generation block includes a clock signal portion with a first frequency and a clock signal portion with a second frequency.

37. The system of claim 36 wherein the clock generation block is disposed within the tester hardware device.

38. The system of claim 36 wherein the clock generation block is disposed within the circuit under test.

39. The system of claim 36 wherein the frequency of the capture input signal is greater than the frequency of the clock input signal.

40. The system of claim 36 wherein the frequency of the clock input signal is greater than the frequency of the capture input signal.
